(19) United States
(12) Patent Application Publication
(10) Pub. No.: US 2026/0267032 A1
(43) Pub. Date: Sep. 10, 2026

(54) METHOD FOR MANUFACTURING METASURFACE WITH IMPROVED EFFICIENCY BY IMPRINTING PROCESS

(71) Applicants: Korea University Research and Business Foundation, Seoul (KR); POSTECH RESEARCH AND BUSINESS DEVELOPMENT FOUNDATION, Pohang-si, Gyeongsangbuk-do (KR)

(72) Inventors: Heon LEE, Seoul (KR); Jun Suk RHO, Pohang-si (KR); Won Joong KIM, Seoul (KR); Joo Hoon KIM, Pohang-si (KR); Ho Jung CHOI, Seoul (KR); Jun Hwa SEONG, Ulsan (KR); Ye Seul KIM, Mokpo-si (KR)

(73) Assignees: Korea University Research and Business Foundation, Seoul (KR); POSTECH RESEARCH AND BUSINESS DEVELOPMENT FOUNDATION, Pohang-si, Gyeongsangbuk-do (KR)

(21) Appl. No.: 19/165,923

(22) PCT Filed: Mar. 16, 2023
(86) PCT No.: PCT/KR2023/003509

§ 371 Date: Sep. 16, 2025

(51) Int. Cl. G02B 1/00; C23C 16/452; C23C 16/455

(52) U.S. Cl. CPC G02B 1/002; C23C 16/452; C23C 16/45525

(57) ABSTRACT

The present invention relates to a technique for manufacturing a metasurface fabricated by an imprinting process with improved efficiency, and more particularly, to a technical concept of fabricating an efficiency-enhanced metasurface by forming nanoantennas using a polymer-based imprint resin and subsequently coating the surface with a high-refractive-index material. According to one embodiment, a method for fabricating a metasurface may comprise: mixing nanoparticles of a nanoantenna material with a photocurable polymer or a thermosetting polymer and applying the mixture onto a substrate; imprinting the photocurable polymer or the thermosetting polymer with an imprint stamp having a surface relief structure and a predetermined pattern to form a structure of the photocurable polymer or the thermosetting polymer on the substrate and curing the structure; and coating a high-refractive-index material on a surface of the cured structure by a deposition process.

### TECHNICAL FIELD

The present invention relates to a technique for manufacturing a metasurface fabricated by an imprinting process with improved efficiency, and more particularly, to a technical concept of fabricating an efficiency-enhanced metasurface by forming nanoantennas using a polymer-based imprint resin and subsequently coating the surface with a high-refractive-index material.

### BACKGROUND ART

A metasurface is a two-dimensional element that performs functions of various optical devices such as lenses and holograms, and is formed in a structure in which nanoantennas having a size on the order of an incident light wavelength are arranged on a plane.

Since a metasurface can perform various optical functions depending on the shape, period, and arrangement of the nanoantennas, it has been attracting attention as a next-generation optical element and has been actively studied, but it has not yet reached the stage of mass production and commercialization.

A metasurface is typically manufactured by depositing a thin film of a nanoantenna material on a substrate and then fabricating nanoantennas through an electron-beam lithography process and an etching process. However, when produced by this method, the manufacturing cost is very high, the production speed is very slow, and it is difficult to fabricate large-area devices, which becomes a major obstacle to commercialization.

Recently, a method of fabricating a metasurface using an imprinting process has emerged as a replacement for conventional thin film deposition, lithography, and etching processes. This method provides the advantages of a much simpler fabrication process and lower process cost compared to conventional methods.

However, this approach requires a high-refractive-index imprint resin (nano-molding material) and an imprint stamp having a nanoscale pattern, and the fabrication of such an imprint stamp may still require an electron-beam lithography process.

Nevertheless, the imprinting process has a significant advantage over conventional processes because an imprint stamp, once fabricated, can be replicated and repeatedly used.

### DISCLOSURE

### Technical Problem

The present invention aims to simplify the fabrication process and reduce the associated cost by forming a metasurface having a patterned layer through an imprinting process.

The present invention further aims to enhance the efficiency of the metasurface by coating various high-refractive-index materials such as a-Si, GaN, and ZrO₂ instead of TiO₂.

The present invention also aims to fabricate a high-efficiency metasurface, which is difficult to obtain through conventional imprinting processes, by molding a nanoantenna structure using either a general imprint resin or an imprint resin containing ZrO₂ nanoparticles, and subsequently coating the structure with a ZrO₂ thin film.

### Technical Solution

According to one embodiment, a method for fabricating a metasurface may comprise: mixing nanoparticles of a nanoantenna material with a photocurable polymer or a thermosetting polymer and applying the mixture onto a substrate; imprinting the photocurable polymer or the thermosetting polymer with an imprint stamp having a surface relief structure and a predetermined pattern to form a structure of the photocurable polymer or the thermosetting polymer on the substrate and curing the structure; and coating a high-refractive-index material on a surface of the cured structure by a deposition process.

In one embodiment, the step of coating the high-refractive-index material on the surface of the cured structure by a deposition process may comprise coating the high-refractive-index material on the surface of the cured structure by at least one deposition process selected from atomic layer deposition (ALD) and plasma-enhanced chemical vapor deposition (PECVD).

In one embodiment, the step of coating the high-refractive-index material on the surface of the cured structure by a deposition process may comprise coating at least one high-refractive-index material selected from TiO₂, a-Si, and ZrO₂.

In one embodiment, the step of coating the high-refractive-index material on the surface of the cured structure by a deposition process may comprise coating the high-refractive-index material in a thickness range of 9 nm to 12 nm.

In one embodiment, the step of imprinting with the imprint stamp having the surface relief structure may comprise pressing the imprint stamp onto the photocurable polymer or the thermosetting polymer under a pressure of 1 to 10 atm and at a temperature of 100° C. to 200° C.

In one embodiment, the step of forming and curing the structure of the photocurable polymer or the thermosetting polymer may comprise annealing the formed structure at a temperature of 300° C. to 1000° C.

### Advantageous Effects

According to one embodiment, since a metasurface having a patterned layer is formed by using an imprinting process, the fabrication process can be simplified and the associated cost can be reduced.

According to one embodiment, by coating various high-refractive-index materials such as a-Si, GaN, and ZrO₂ instead of TiO₂, the efficiency of the metasurface can be improved.

According to one embodiment, by molding a nanoantenna structure using either a general imprint resin or an imprint resin containing ZrO₂ nanoparticles and subsequently coating the structure with a ZrO₂ thin film, a high-efficiency metasurface, which is difficult to obtain through conventional imprinting processes, can be fabricated.

### DESCRIPTION OF DRAWINGS

FIG. 1 is a diagram illustrating a metasurface according to one embodiment.

FIGS. 2a to 2c are diagrams illustrating a method for fabricating a metasurface according to one embodiment.

FIG. 3a is a diagram showing the efficiency of a nanometalens formed with a general imprint resin according to variations in the width and length of nanoantennas.

FIG. 3b is a diagram showing the efficiency of a nanometalens formed with an imprint resin containing ZrO₂ nanoparticles according to variations in the width and length of nanoantennas.

FIG. 4 is a diagram showing the efficiency of a metalens according to variations in the thickness of the coated ZrO₂.

### BEST MOD

Specific structural or functional descriptions of embodiments according to the concept of the present invention disclosed herein are merely illustrated for the purpose of describing the embodiments according to the concept of the present invention, and the embodiments according to the concept of the present invention may be implemented in various forms and are not limited to the embodiments described herein.

Since the embodiments according to the concept of the present invention may be subject to various modifications and may take various forms, the embodiments will be illustrated in the drawings and described in detail in the specification. However, this is not intended to limit the embodiments according to the concept of the present invention to specific disclosed forms, but rather to include modifications, equivalents, or alternatives that fall within the spirit and scope of the present invention.

Terms such as “first” or “second” may be used to describe various elements, but such elements should not be limited by the terms. The terms are used only to distinguish one element from another, and for example, without departing from the scope of the present invention, a first element may be designated as a second element, and similarly, a second element may be designated as a first element.

When an element is referred to as being “connected” or “coupled” to another element, it should be understood that the element may be directly connected or coupled to the other element, or intervening elements may be present. In contrast, when an element is referred to as being “directly connected” or “directly coupled” to another element, it should be understood that no intervening elements are present. Expressions describing relationships between elements, such as “between,” “directly between,” or “adjacent to,” should be interpreted in the same manner.

The terminology used in this specification is for the purpose of describing particular embodiments only and is not intended to limit the present invention. Singular forms are intended to include plural forms unless the context clearly dictates otherwise. As used herein, the terms “comprise” and “have” specify the presence of stated features, integers, steps, operations, elements, parts, or combinations thereof, but do not preclude the presence or addition of one or more other features, integers, steps, operations, elements, parts, or combinations thereof.

Unless otherwise defined, all terms used herein, including technical and scientific terms, have the same meaning as commonly understood by one of ordinary skill in the art to which this invention belongs. Terms defined in generally used dictionaries should be interpreted as having meanings consistent with their usage in the relevant technical context, and unless expressly defined in this specification, they should not be interpreted in an idealized or overly formal sense.

Hereinafter, embodiments will be described in detail with reference to the accompanying drawings. However, the scope of the patent application is not limited or restricted to such embodiments. The same reference numerals in the drawings denote the same elements.

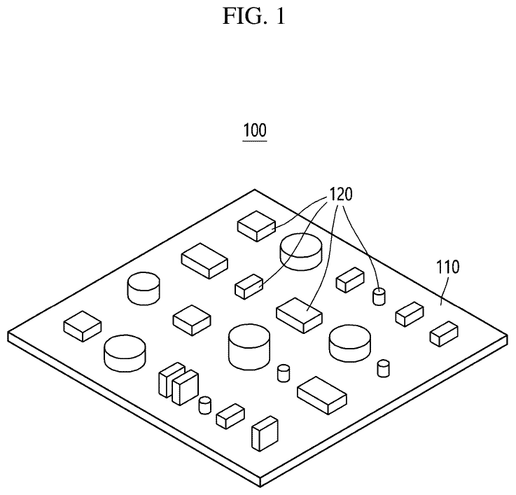

FIG. 1 is a diagram illustrating a metasurface 100 according to one embodiment.

The metasurface 100 according to one embodiment is a next-generation element formed by an array of nanoantennas and is also referred to as a metalens.

Specifically, the metasurface 100 may form a nanoantenna array layer on a plane to create a two-dimensional planar lens that replaces the function of a three-dimensional lens, which is referred to as a metalens or metasurface. A metalens is fabricated by arranging nanoantennas having a size on the order of an incident light wavelength at predetermined positions on a substrate, and is generally manufactured through processes including thin film formation of a nanoantenna material (e.g., Au, TiO₂, ZrO₂, GaN, Si, etc.) on the substrate, electron-beam lithography, reactive ion etching, and resist ashing, thereby forming a nanopattern of the nanoantenna material on the substrate.

Meanwhile, an advanced method for fabricating the metasurface 100 is a nanoimprinting process, in which nanoparticles of a nanoantenna material are mixed with a photocurable polymer or a thermosetting polymer and applied onto a substrate. The mixture is then pressed with an imprint stamp having a surface relief structure to form a nanostructure shape, followed by curing the nanoparticle-polymer mixture with light or heat and subsequently removing the imprint stamp to form a nanopattern, i.e., a nanoantenna array, on the substrate surface.

The size and period of the nanoantennas formed on the metasurface 100 are approximately on the order of the wavelength of the controlled light, and when the nanoantennas are fabricated with a higher-refractive-index material, their height and aspect ratio can be reduced. The nanoantennas used in the metasurface 100 may be fabricated in various shapes. The light incident on the metasurface can have its phase and wavefront independently controlled by each nanoantenna.

Aberrations of conventional lenses, such as chromatic aberration, spherical aberration, and coma aberration, can be eliminated through the design of individual nanoantennas, thereby enabling the fabrication of a perfect lens through the metasurface 100.

The present invention utilizes the fact that the interaction between nanoantennas and light is primarily determined by the physical properties of the surfaces of the nanoantennas. From the viewpoint of nano-molding, the invention also leverages the fact that nano-molding using an imprint resin composed of a pure polymer is a much simpler process compared to nano-molding using a high-refractive-index imprint resin containing nanoparticles.

Nanoantennas fabricated by etching a TiO₂ thin film exhibit the most excellent optical characteristics, but the process is complicated and the cost is very high. In addition, mass production is very difficult. Nanoantennas fabricated by imprinting with a polymer resin have the simplest nano-molding process itself, but are not suitable for configuring the metasurface 100.

When nanoantennas are fabricated by imprinting with a high-refractive-index resin made by mixing nanoparticles of a high-refractive-index material into a polymer, the process is most advantageous in terms of ease and process cost. However, the efficiency of a metasurface fabricated with such nanoantennas is lower than that of a metasurface fabricated by etching a thin film.

Accordingly, the present invention provides a way to fabricate the nanoantennas forming the metasurface easily while also enhancing the optical characteristics, by molding nanoantennas with a general imprint resin or a high-refractive-index resin containing nanoparticles, and subsequently coating the surface by a thin film deposition method having excellent conformality such as ALD or PECVD, thereby enabling the fabrication of a metasurface 100 with excellent efficiency.

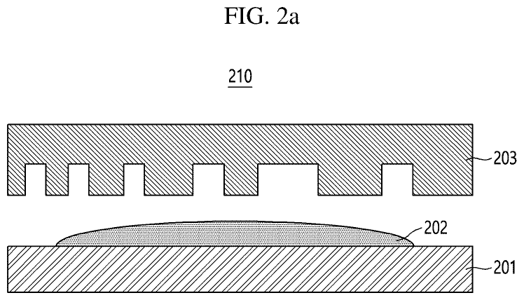

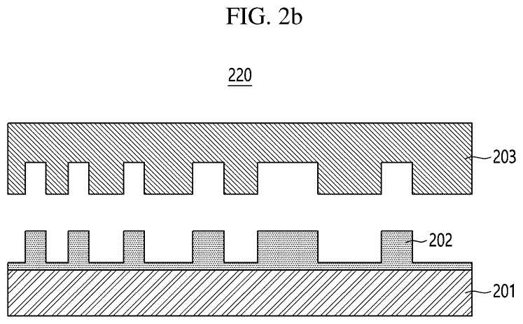

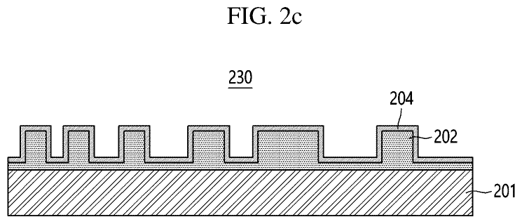

FIGS. 2a to 2c are diagrams illustrating a method for fabricating a metasurface according to one embodiment.

According to one embodiment, a method for fabricating a metasurface may form a metasurface (metalens) in which a high-refractive-index material such as TiO₂, a-Si, or ZrO₂ is coated on a structure formed of a photocurable polymer (general UV imprint resin) or a polymer mixed with nanoparticles (high-refractive-index imprint resin).

In addition, the nanoantennas of the metasurface may be fabricated by imprinting a photocurable polymer or a polymer mixed with nanoparticles, followed by thin film coating of a high-refractive-index material such as TiO₂, a-Si, or ZrO₂ through ALD or PECVD.

As for the structure and fabrication method of the metasurface, the essential feature of the present invention is that nanoantenna structures are easily formed on a substrate by an imprinting process, and then a high-refractive-index material is coated thereon by a conformal coating method such as ALD or PECVD, thereby obtaining a metasurface with improved efficiency.

To this end, as shown by reference numeral 210 in FIG. 2a, the method for fabricating a metasurface according to one embodiment may comprise mixing nanoparticles of a nanoantenna material with a photocurable polymer or a thermosetting polymer 202 and applying the mixture onto a substrate 201.

In addition, the method for fabricating a metasurface according to one embodiment may comprise imprinting the photocurable polymer or the thermosetting polymer 202 with an imprint stamp 203 having a surface relief structure and a predetermined pattern.

As shown by reference numeral 220 in FIG. 2b, a structure of the photocurable polymer or the thermosetting polymer 202 may be formed on the substrate 201 and cured.

For example, in order to perform imprinting with an imprint stamp having a surface relief structure, the imprint stamp may be pressed onto the photocurable polymer or the thermosetting polymer under a pressure of 1 to 10 atm and at a temperature of 100° C. to 200° C.

In addition, the method for fabricating a metasurface according to one embodiment may comprise annealing the formed structure at a temperature of 300° C. to 1000° C. to cure the structure.

As shown by reference numeral 230, the method for fabricating a metasurface according to one embodiment may comprise coating a high-refractive-index material 204 on a surface of the cured structure by a deposition process.

The method for fabricating a metasurface according to one embodiment may include a process of fabricating by e-beam lithography and etching, a process of fabricating by imprinting with a high-refractive-index resin containing nanoparticles, and a process of fabricating by imprinting and subsequently coating with a thin film.

In this process, the thin film of the high-refractive-index material 204 may be coated by at least one deposition process selected from atomic layer deposition (ALD) and plasma-enhanced chemical vapor deposition (PECVD).

For example, in order to coat a high-refractive-index material on a surface of the cured structure by a deposition process, at least one high-refractive-index material selected from TiO₂, a-Si, or ZrO₂ may be coated.

In addition, the high-refractive-index material may be coated in a thickness range of 9 nm to 12 nm.

By coating various high-refractive-index materials such as a-Si, GaN, and ZrO₂ instead of TiO₂, the efficiency of the metasurface can be improved.

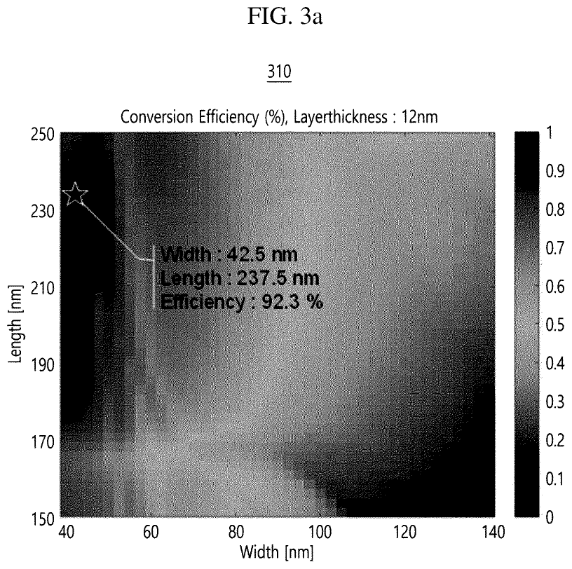

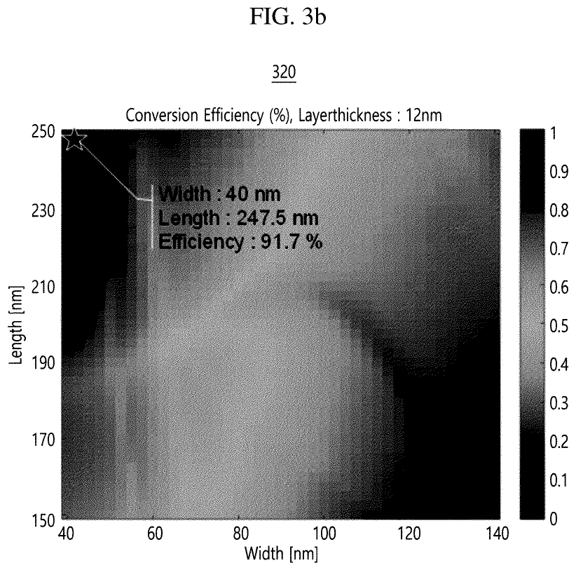

FIG. 3a is a diagram 310 showing the efficiency of a nanometalens formed with a general imprint resin according to variations in the width and length of nanoantennas.

FIG. 3b is a diagram showing the efficiency of a nanometalens formed with an imprint resin containing ZrO₂ nanoparticles according to variations in the width and length of nanoantennas.

The present invention illustrates an embodiment of nanoantennas using a ZrO₂ material. In particular, as shown by reference numeral 310 in FIG. 3a, when nanoantennas are molded with a high-refractive-index imprint resin containing ZrO₂ nanoparticles, the height of the nanoantennas is fixed at 600 nm and the thickness of the coated ZrO₂ is fixed at 12 nm, and the efficiency of the metasurface is calculated according to variations in the width and length of the nanoantennas.

In addition, as shown by reference numeral 320 in FIG. 3b, when nanoantennas are molded with a general imprint resin without nanoparticles, the height of the nanoantennas is fixed at 600 nm and the thickness of the coated ZrO₂ is fixed at 12 nm, and the efficiency of the metasurface is calculated according to variations in the width and length of the nanoantennas.

When molded with a high-refractive-index imprint resin, a metasurface having a high efficiency of 92.3% is obtained at width=42.5 nm and length=237.5 nm. When molded with a general imprint resin without nanoparticles and coated with a ZrO₂ thin film, a metasurface having a high efficiency of 91.7% is obtained at width=40 nm and length=247.5 nm.

That is, by molding a nanoantenna structure with either a general imprint resin or an imprint resin containing ZrO₂ nanoparticles, and subsequently coating with a ZrO₂ thin film, it is possible to fabricate a metasurface (metalens) with high efficiency of about 92%, which is difficult to achieve through conventional imprinting processes.

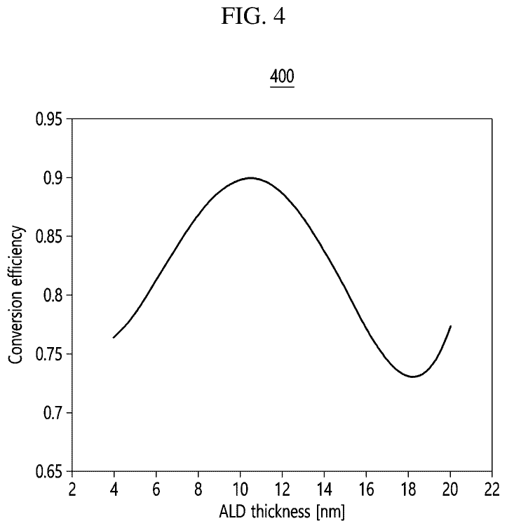

FIG. 4 is a diagram 400 showing the efficiency of a metalens according to variations in the thickness of the coated ZrO₂.

Reference numeral 400 is a graph showing the efficiency of a nanometalens formed with a general imprint resin and an imprint resin containing ZrO₂ nanoparticles, coated with 12 nm of ZrO₂, according to variations in the width and length of the nanoantennas.

The present invention can form a metasurface composed of nanoantennas having a multilayer structure by molding nanoantenna shapes with a polymer or a high-refractive-index resin instead of a single material nanoantenna, and subsequently coating the surfaces of the nanoantennas with a thin film of a high-refractive-index material such as TiO₂, a-Si, or ZrO₂ using a process such as ALD or PECVD.

Even when molded with a general imprint resin without nanoparticles at the optimized nanoantenna dimensions of width=42.5 nm, length=237.5 nm, and height=600 nm, which correspond to molding with a high-refractive-index imprint resin containing nanoparticles, a high efficiency of 90.2% can still be obtained by coating with 12 nm of ZrO₂.

In particular, FIG. 4 shows the efficiency of a metalens as the thickness of the ZrO₂ coated on the imprinted nanoantennas varies, and it indicates that the efficiency remains higher than 90% while the thickness of the ZrO₂ varies from 9 nm to 12 nm.

The present invention relates to a metasurface (metalens) as a next-generation optical element. Since the two-dimensional metasurface can replace all functions of a conventional three-dimensional lens, it can significantly reduce the form factor of existing optical devices.

In particular, according to one embodiment, when generating a metasurface by using the imprinting process of the present invention, a metasurface having a patterned layer can be formed, thereby simplifying the fabrication process and reducing the associated cost.

According to one embodiment, by coating various high-refractive-index materials such as a-Si, GaN, and ZrO₂ instead of TiO₂, the efficiency of the metasurface can be improved.

According to one embodiment, by molding a nanoantenna structure with either a general imprint resin or an imprint resin containing ZrO₂ nanoparticles and subsequently coating with a ZrO₂ thin film, it is possible to fabricate a high-efficiency metasurface that is difficult to obtain through conventional imprinting processes.

In the above-described specific embodiments, the components included in the invention have been expressed in singular or plural depending on the particular embodiment presented.

However, the expressions in singular or plural are selected as appropriate to the situation for the convenience of description, and the embodiments described above are not limited to components in singular or plural form. A component expressed in plural may be configured as a single component, and a component expressed in singular may be configured as multiple components.

Meanwhile, although the invention has been described with reference to specific embodiments, it is of course possible to make various modifications within the scope that does not depart from the technical spirit encompassed by the various embodiments.

Therefore, the scope of the present invention should not be determined as limited to the described embodiments, but should be defined not only by the following claims, but also by equivalents thereof.

1. A method for fabricating a metasurface, comprising:
mixing nanoparticles of a nanoantenna material with a photocurable polymer or a thermosetting polymer and applying the mixture onto a substrate;
imprinting the photocurable polymer or the thermosetting polymer with an imprint stamp having a surface relief structure and a predetermined pattern to form a structure of the photocurable polymer or the thermosetting polymer on the substrate and curing the structure; and
coating a high-refractive-index material on a surface of the cured structure by a deposition process.

2. The method of claim 1, wherein the step of coating the high-refractive-index material on the surface of the cured structure comprises coating the high-refractive-index material by at least one deposition process selected from atomic layer deposition (ALD) and plasma-enhanced chemical vapor deposition (PECVD).

3. The method of claim 1, wherein the step of coating the high-refractive-index material on the surface of the cured structure comprises coating at least one high-refractive-index material selected from TiO₂, a-Si, and ZrO₂.

4. The method of claim 1, wherein the step of coating the high-refractive-index material on the surface of the cured structure comprises coating the high-refractive-index material in a thickness range of 9 nm to 12 nm.

5. The method of claim 1, wherein the step of imprinting with the imprint stamp having the surface relief structure comprises pressing the imprint stamp onto the photocurable polymer or the thermosetting polymer under a pressure of 1 to 10 atm and at a temperature of 100° C. to 200° C.

6. The method of claim 1, wherein the step of forming and curing the structure of the photocurable polymer or the thermosetting polymer comprises annealing the formed structure at a temperature of 300° C. to 1000° C.

7. An optical element comprising a metasurface fabricated by the method according to claim 1.
